(19) United States
(12) Patent Application Publication
(10) Pub. No.: US 2007/0178609 A1
(43) Pub. Date: Aug. 2, 2007

(54) Magnetoresistive element manufacturing method and magnetic memory device manufacturing method

(76) Inventor: Hiroaki Yoda, Sagamihara-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/398,647

(22) Filed: Apr. 6, 2006

(30) Foreign Application Priority Data
Jan. 30, 2006 (JP) 2006-021278

(51) Int. Cl. H01L 21/00

(52) U.S. Cl. 438/3

(57) ABSTRACT

A magnetoresistive element manufacturing method includes forming a material layer on a substrate, the material layer including a fixed layer, a recording layer, and a first nonmagnetic layer sandwiched between the fixed layer and the recording layer; forming a mask material on the material layer, forming a first mask with a desired pattern by processing the mask material by using imprint lithography, and forming a magnetoresistive element with the desired pattern by processing the material layer by using the first mask.

### CROSS-REFERENCE TO RELATED APPLICATIONS

This application is based upon and claims the benefit of priority from prior Japanese Patent Application No. 2006-021278, filed Jan. 30, 2006, the entire contents of which are incorporated herein by reference.

### BACKGROUND OF THE INVENTION

1. Field of the Invention

The present invention relates to a magnetoresistive element manufacturing method and a magnetic memory device manufacturing method.

2. Description of the Related Art

A magnetoresistive random access memory (MRAM) has been expected and developed recently as an ultimate memory that implements nonvolatility, high speed, and large capacity (e.g., Roy Scheuerlein et al., “A 10 ns Read and Write Non-Volatile Memory Array Using a Magnetic Tunnel Junction and FET Switch in each Cell”, ISSCC 2000 Technical Digest, p. 128. The largest problem of this magnetoresistive random access memory is a variation in the reversal field threshold value of a memory cell.

FIG. 17 is a schematic perspective view of a magnetoresistive random access memory according to a prior art. FIG. 18 shows the ideal curve of the reversal field threshold value of a memory cell of the magnetoresistive random access memory according to the prior art. FIG. 19 shows the actual curve of the reversal field threshold value of a memory cell of the magnetoresistive random access memory according to the prior art.

As shown in FIG. 17, write currents are supplied to a bit line BL and a word line WL, respectively. Data is selectively written in only a selected cell SC located at the intersection between the bit line BL and the word line WL by the synthetic field of magnetic fields generated by the write currents. The write in only the selected cell SC is implemented when the reversal field threshold value has a curve shown in FIG. 18. Actually, since the curve of the reversal field threshold value varies, as shown in FIG. 19, write errors occur in semi-selected cells SC1, SC2, and SC3.

### BRIEF SUMMARY OF THE INVENTION

According to a first aspect of the present invention, there is provided a magnetoresistive element manufacturing method comprising: forming a material layer on a substrate, the material layer including a fixed layer, a recording layer, and a first nonmagnetic layer sandwiched between the fixed layer and the recording layer; forming a mask material on the material layer; forming a first mask with a desired pattern by processing the mask material by using imprint lithography; and forming a magnetoresistive element with the desired pattern by processing the material layer by using the first mask.

According to a second aspect of the present invention, there is provided a magnetic memory device manufacturing method comprising: forming a material layer on a substrate, the material layer including a fixed layer, a recording layer, and a nonmagnetic layer sandwiched between the fixed layer and the recording layer; forming a mask material on the material layer; forming a first mask with a desired pattern by processing the mask material by using imprint lithography; forming a magnetoresistive element with the desired pattern by processing the material layer by using the first mask; and forming a bit line and a word line above and under the magnetoresistive element.

### BRIEF DESCRIPTION OF THE SEVERAL VIEWS OF THE DRAWING

FIGS. 1A to 1D are sectional views showing steps in manufacturing an MTJ element by using imprint lithography according to the first embodiment of the present invention;

FIG. 2 is a plan view showing an MTJ element formed by using imprint lithography according to the first embodiment of the present invention;

FIG. 3A is a graph showing the curve of a reversal field threshold value when photolithography is used;

FIG. 3B is a graph showing the curve of a reversal field threshold value when imprint lithography according to the first embodiment of the present invention is used;

FIG. 4 is a plan view showing a cross-shaped MTJ element formed by using imprint lithography according to the first embodiment of the present invention;

FIGS. 5A and 5B are views for explaining the relationship between a write margin and the radius of curvature of the MTJ element according to the first embodiment of the present invention;

FIG. 6 is a graph showing a change in the resistance of an MTJ element according to the second embodiment of the present invention;

FIGS. 7A to 7K are views showing examples of the planar shape of the MTJ element according to the second embodiment of the present invention;

FIGS. 8A and 8B are views showing examples of the sectional shape of the MTJ element according to the second embodiment of the present invention;

FIG. 9 is a sectional view showing an MTJ element with a double junction structure according to the second embodiment of the present invention;

FIGS. 10A and 10B are views showing select transistor memory cells of a magnetoresistive random access memory according to the third embodiment of the present invention;

FIGS. 11A and 11B are views showing select diode memory cells of the magnetoresistive random access memory according to the third embodiment of the present invention;

FIGS. 12A and 12B are views showing cross-point memory cells of the magnetoresistive random access memory according to the third embodiment of the present invention;

FIG. 13 is a plan view showing a toggle memory cell of the magnetoresistive random access memory according to the third embodiment of the present invention;

FIG. 14 is a sectional view of an MTJ element according to an embodiment of the present invention;

FIGS. 15A and 15B are views showing the planar shape of the MTJ element according to an embodiment of the present invention after exposure;

FIG. 16 is a view showing a problem of coupling according to an embodiment of the present invention;

FIG. 17 is a schematic perspective view showing a magnetoresistive random access memory according to a prior art;

FIG. 18 is a graph showing the ideal curve of the reversal field threshold value of a memory cell of the magnetoresistive random access memory according to the prior art; and

FIG. 19 is a graph showing the actual curve of the reversal field threshold value of a memory cell of the magnetoresistive random access memory according to the prior art.

### DETAILED DESCRIPTION OF THE INVENTION

In recent years, a magnetic tunneling junction (MTJ) element is used as a magnetoresistive element of a magnetoresistive random access memory (MRAM).

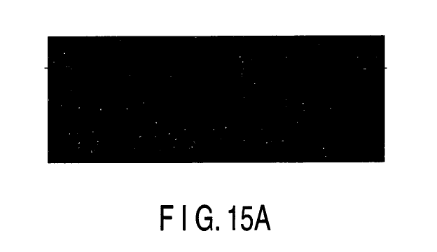

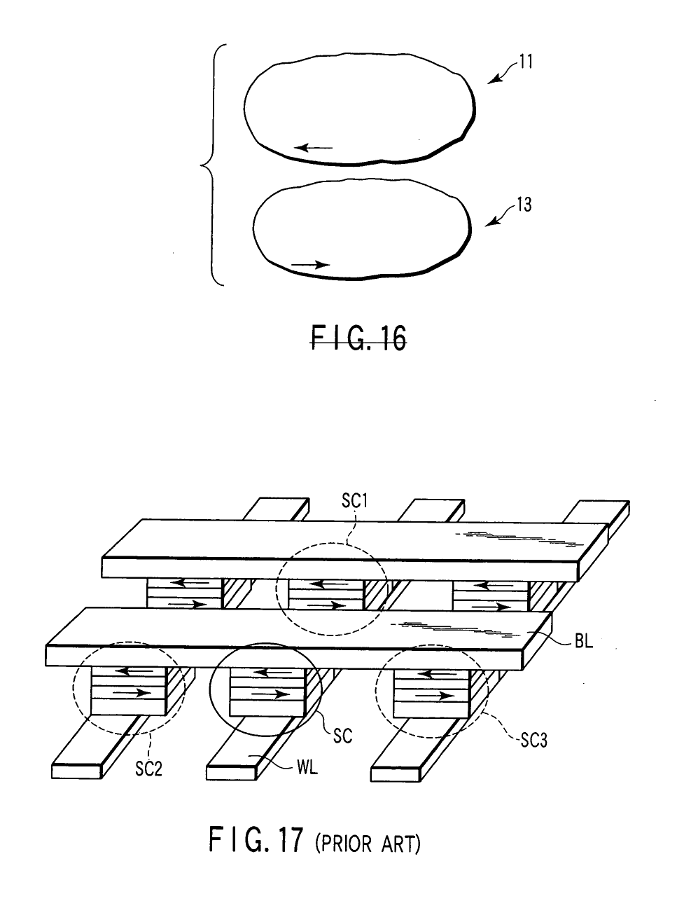

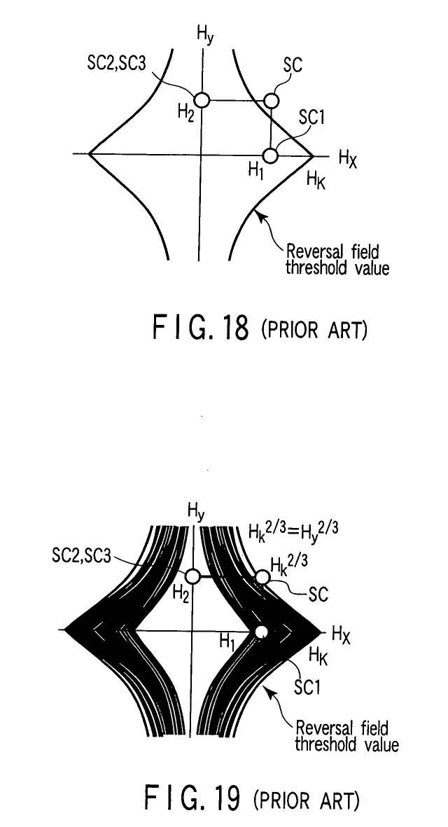

FIG. 14 is a sectional view of an MTJ element according to an embodiment of the present invention. FIGS. 15A and 15B show the planar shape of the MTJ element according to an embodiment of the present invention after exposure. FIG. 16 shows a problem of magnetic coupling according to an embodiment of the present invention.

As shown in FIG. 14, an MTJ element 10 has a fixed layer (a pinned layer) 11 with a fixed magnetization direction, a recording layer (a free layer) 13 whose magnetization direction reverses in the horizontal direction, and a tunnel barrier layer 12 sandwiched between the fixed layer 11 and the recording layer 13.

One cause of the variation in the reversal field threshold value is a variation in the width of the recording layer 13. Magnetoresistive random access memories were formed while reducing the variation in the width, and the variation in the reversal field threshold value was evaluated. The variation in the reversal field threshold value could not be reduced to a predetermined value or less. Note that the reversal field threshold value indicates a magnetic field with a threshold value at which the magnetization of the recording layer 13 reverses.

When the MTJ element 10 after exposure was observed two-dimensionally, unevenness remained in the edge of the MTJ element 10, as shown in FIGS. 15A and 15B. In this uneven portion, the magnetization of the fixed layer 11 and that of the recording layer 13 caused local magnetic coupling, as shown in FIG. 16, so that the reversal field threshold value varied. Deposition sticking to the edge became nonuniform because of the uneven edge. This exaggerated the unevenness of the edge so that the variation in the reversal field threshold value was about 8%.

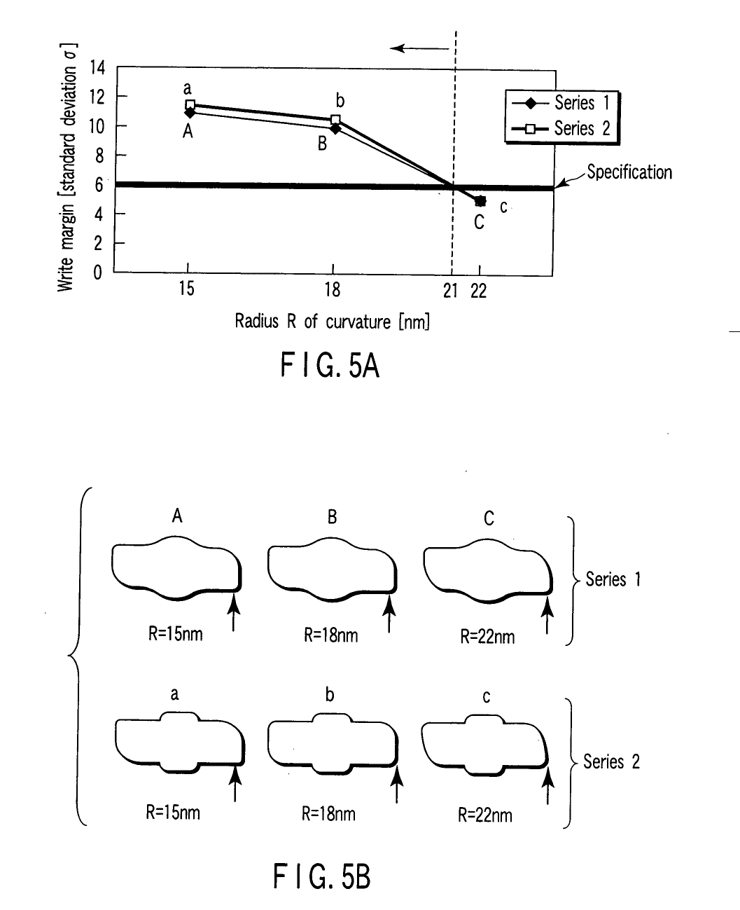

More detailed analysis revealed that the unevenness remaining in the edge of the recording layer 13 was one of major causes of the variation in the reversal field threshold value. The unevenness around the recording layer 13 was reduced by processing it using a high-resolution tool such as electron beam (EB) lithography. As a result, the variation in the reversal field threshold value could be reduced to near the target value but not beyond it. To normally operate all bits of a megabit-class magnetoresistive random access memory, the variation in the reversal field threshold value is preferably reduced to about 5% (1σ) in standard deviation. This will be described in detail with reference to FIGS. 5A and 5B.

In the embodiments of the present invention, the variation in the reversal field threshold value is reduced by highly accurately processing an MTJ element on the basis of the above-described analysis result. The embodiments of the present invention will be described below with reference to the accompanying drawing. The same reverence numerals denote the same parts throughout the drawing.

### FIRST EMBODIMENT

In the first embodiment, imprint lithography (also called nanoimprint lithography) is used to process an MTJ element. Imprint lithography allows formation of a fine structure on the order of nanometer without using a large-scaled expensive apparatus in photolithography or the like.

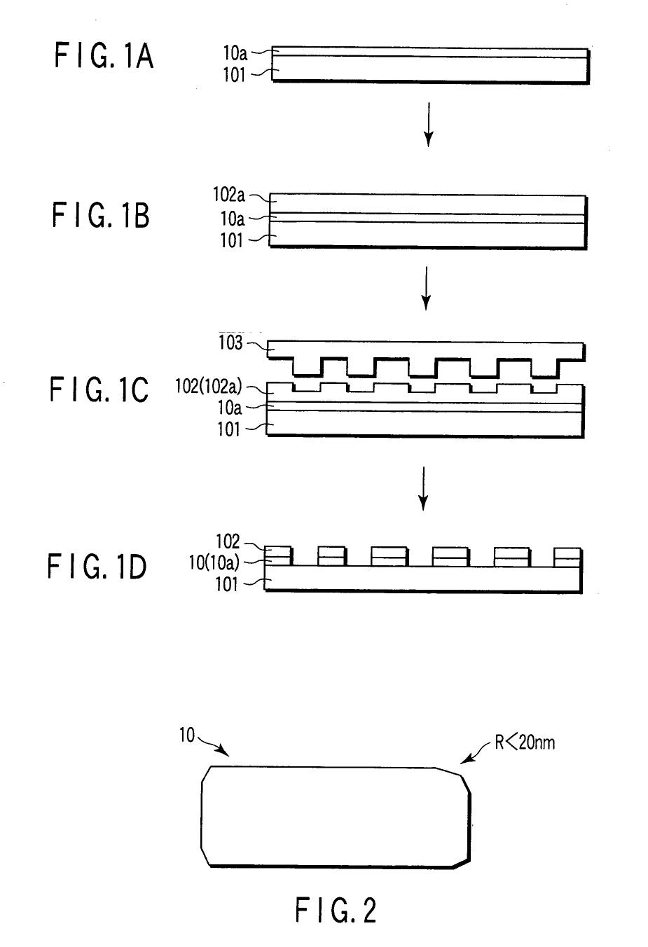

FIGS. 1A to 1D are sectional views showing steps in manufacturing an MTJ element by using imprint lithography according to the first embodiment of the present invention. FIG. 2 is a plan view showing an MTJ element formed by using imprint lithography according to the first embodiment of the present invention. An MTJ element manufacturing method using imprint lithography according to the first embodiment of the present invention will be described below.

As shown in FIG. 1A, an MTJ material layer 10a is formed on a substrate 101 by, e.g., sputtering. The MTJ material layer 10a is a material layer including a fixed layer 11, tunnel barrier layer 12, and recording layer 13.

As shown in FIG. 1B, a mask material layer 102a made of, e.g., a thermosetting material or photo-setting material is applied to the MTJ material layer 10a.

As shown in FIG. 1C, a mold 103 having an accurate three-dimensional pattern formed by, e.g., EB lithography is prepared. Preferably, the mold 103 has a high wetting and is easy to peel off after the mask material layer 102a is set. The mold 103 is pressed against the substrate 101 by, e.g., a pressing machine. After the mask material layer 102a is set in the three-dimensional pattern, the mold 103 is separated from the mask material layer 102a. With this process, a mask 102 having the three-dimensional pattern is formed. The separated mold 103 can be used repeatedly.

As shown in FIG. 1D, the three-dimensional pattern is transferred to the MTJ material layer 10a by anisotropic dry etching such as reactive ion etching (RIE) by using the mask 102. AN MTJ element 10 patterned into a desired shape is formed (FIG. 2). The mask 102 is removed.

Detail examples of the manufacturing method by imprint lithography will be described. A method using a thermosetting material as the mask material layer 102a (thermosetting imprint lithography) and a method using a photo-setting material as the mask material layer 102a (photo-setting imprint lithography) will be described.

In thermosetting imprint lithography, a resist such as polymethyl methacrylate (PPMA) is used as the mask material layer 102a. First, the mold 103 is pressed against the substrate 101 with a heated resist being applied on it. The temperature of the resist is lowered to set the resist. Then, the mold 103 is separated. With this process, the three-dimensional pattern of the mold 103 is transferred to the resist. The resist with the transferred three-dimensional pattern is entirely thinned by using, e.g., oxygen plasma to expose the MTJ material layer 10a. The three-dimensional pattern is transferred to the MTJ material layer 10a by executing, e.g., dry etching.

In photo-setting imprint lithography, quartz is used as the mold 103, and a photo-setting resin is used as the mask material layer 102a. First, the mold 103 is pressed against the substrate 101 with the photo-setting resin being applied on it. The substrate is irradiated with UV light from the upper surface of the mold 103 to set the photo-setting resin. The mold 103 is separated from the photo-setting resin. With this process, the three-dimensional pattern of the mold 103 is transferred to the photo-setting resin. The three-dimensional pattern is transferred to the MTJ material layer 10a by using the photo-setting resin with the three-dimensional pattern.

Examples of formation of the MTJ element 10 by mask process using imprint lithography will be described below in detail.

### EXAMPLE 1

In Example 1, a mask material was processed by using imprint lithography, and both a recording layer 13 and fixed layer 11 of an MTJ element 10 were processed by using the mask material as a mask.

In the MTJ element 10 in which both the recording layer 13 and the fixed layer 11 were processed by using a mask formed by imprint lithography, as in Example 1, the variation in the reversal field threshold value could be reduced to about 4%. When both the recording layer 13 and the fixed layer 11 were processed, the edge of the recording layer 13 and that of the fixed layer 11 could be formed in a self-aligned manner. The variation in the leakage field from the magnetization of the edge of the fixed layer 11 decreased. As a result, the variation in the reversal field threshold value of the recording layer 13 could be reduced.

### EXAMPLE 2

In Example 2, a mask material was processed by using imprint lithography, and a recording layer 13 of an MTJ element 10 was processed by using the mask material as a mask. A fixed layer 11 was separately processed.

In the MTJ element 10 in which only the recording layer 13 was processed by using a mask formed by imprint lithography, as in Example 2, the variation in the reversal field threshold value could be reduced to about 3.5%. The fixed layer 11 was processed independently of the recording layer 13 to keep the edge of the fixed layer 11 away from the edge of the recording layer 13. For this reason, the influence of the variation in the leakage field from the magnetization of the edge of the fixed layer 11 could be reduced. As a result, the variation in the reversal field threshold value could be reduced.

In this case, the fixed layer 11 is processed by using a mask formed by normal photolithography.

### EXAMPLE 3

In Example 3, a mask material was processed by using imprint lithography, and a recording layer 13 of an MTJ element 10 was processed with a radius R of curvature of 21 nm or less by using the mask material as a mask.

When the mask material was processed by using imprint lithography, as in Example 3, the radius R of curvature of the corner of the recording layer 13 could stably be processed to 21 nm or less (FIG. 2).

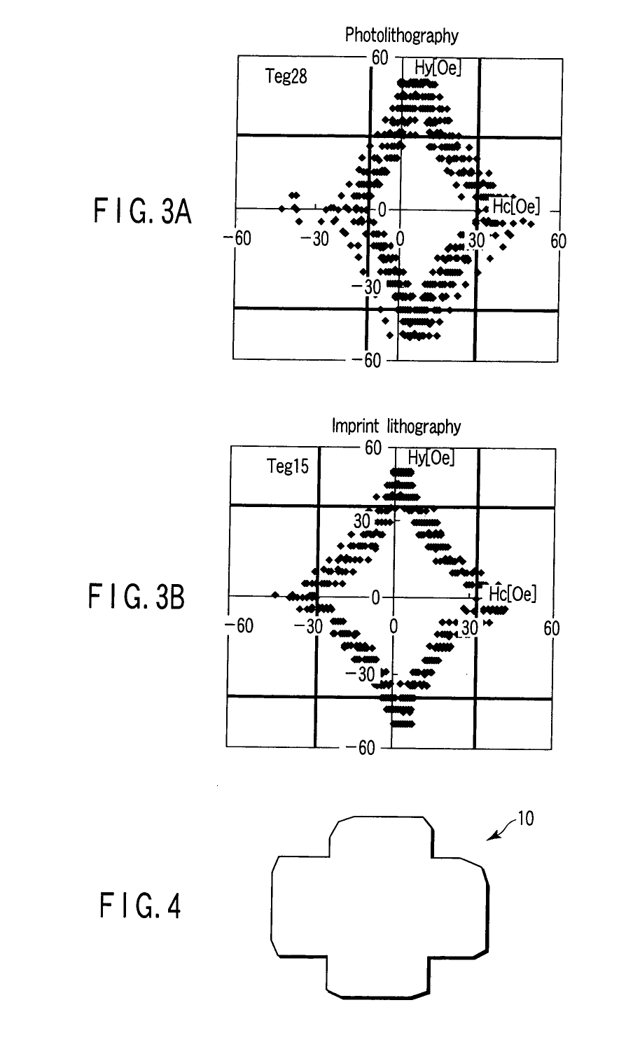

When normal photolithography was used, the reversal field threshold value varied largely, as shown in FIG. 3A. However, when imprint lithography was used as in Example 3, the variation in the reversal field threshold value decreased, as shown in FIG. 3B. Hence, according to Example 3, the variation in the curve of the reversal field threshold value could be suppressed, and a large write margin could be ensured. Especially, when the MTJ element 10 had an almost cross planar shape as shown in FIG. 4, a high margin could be ensured stably.

FIGS. 5A and 5B are views for explaining the relationship between a write margin and the radius of curvature of the MTJ element according to the first embodiment of the present invention. FIG. 5A shows changes in the write margin when MTJ elements shown in FIG. 5B are used.

The write margin will be described. Referring to FIG. 5A, the ordinate represents the write margin, and σ represents the standard deviation of the reversal current value variation of the MTJ element. A magnetoresistive random access memory of 256-Mb (megabit) has a sub-array of about 1 Mb. One Mb corresponds to about 5σ. When a margin of 1σ is ensured, the 1-Mb sub-array operates with a write margin of about 6σ. The specification of the write margin is 6σ.

The cross-shaped MTJ element as the object of this example will be described next. FIG. 5B shows types A, B, and C of series 1 and types a, b, and c of series 2 when the radius R of curvature of the MTJ element is 15, 18, and 22 nm. In the types A, B, and C of series 1, the proximal portion of a projecting portion in the magnetization hard-axis direction of the MTJ element is curved. In the types a, b, and c of series 2, the proximal portion of a projecting portion in the magnetization hard-axis direction of the MTJ element is angular.

When examinations were done using these MTJ elements, the write margin decreased as the radius R of curvature of the MTJ element 10 increased, as shown in FIG. 5A. Considering that the specification of the write margin is 6σ, the radius R of curvature of the MTJ element is preferably 21 nm or less. This applies to both series 1 and 2 of different shapes. When the radius R of curvature of the MTJ element is 21 nm or less, the write margin can be ensured, and the variation in the reversal current value can be reduced.

According to the first embodiment, when the mask material layer 102a is processed by imprint lithography, the mask 102 almost corresponding to the mold can be formed. When the mold 103 with good linearity of dimensions and edge is selectively used, the mask 102 can also be formed with stable linearity of dimensions and edge. When the MTJ element 10 is processed by using the mask 102, the variation in the edge of the MTJ element 10 can be reduced. In addition, the MTJ element 10 having the radius R of curvature of 21 nm or less can be formed. Hence, the variation in the reversal field threshold value can be reduced. Even in a megabit-class magnetoresistive random access memory, all bits can be operated normally. Furthermore, the yield of chips can greatly be increased.

### SECOND EMBODIMENT

In the second embodiment, an MTJ element formed by using a mask by imprint lithography will be described.

### (a) Change in Resistance

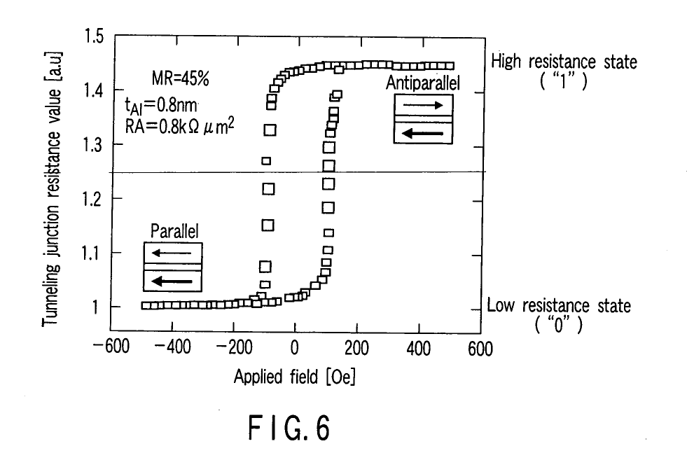

FIG. 6 shows a change in the resistance of an MTJ element according to the second embodiment of the present invention. The change in the resistance of the MTJ element will be described below.

As shown in FIG. 6, “1” and “0” write is implemented by the change in the resistance of an MTJ element 10. The “1” or “0” information is determined depending on the magnetization directions of a fixed layer 11 and recording layer 13, i.e., parallel or antiparallel. “Parallel” indicates that the fixed layer 11 and recording layer 13 have the same magnetization direction. “Antiparallel” indicates that the fixed layer 11 and recording layer 13 have reverse magnetization directions.

In the parallel state, the tunnel resistance of a tunnel barrier layer 12 is lowest. This state is defines as a “0” state. In the antiparallel state, the tunnel resistance of a tunnel barrier layer 12 is highest. This state is defined as a “1” state.

### (b) Planar Shape

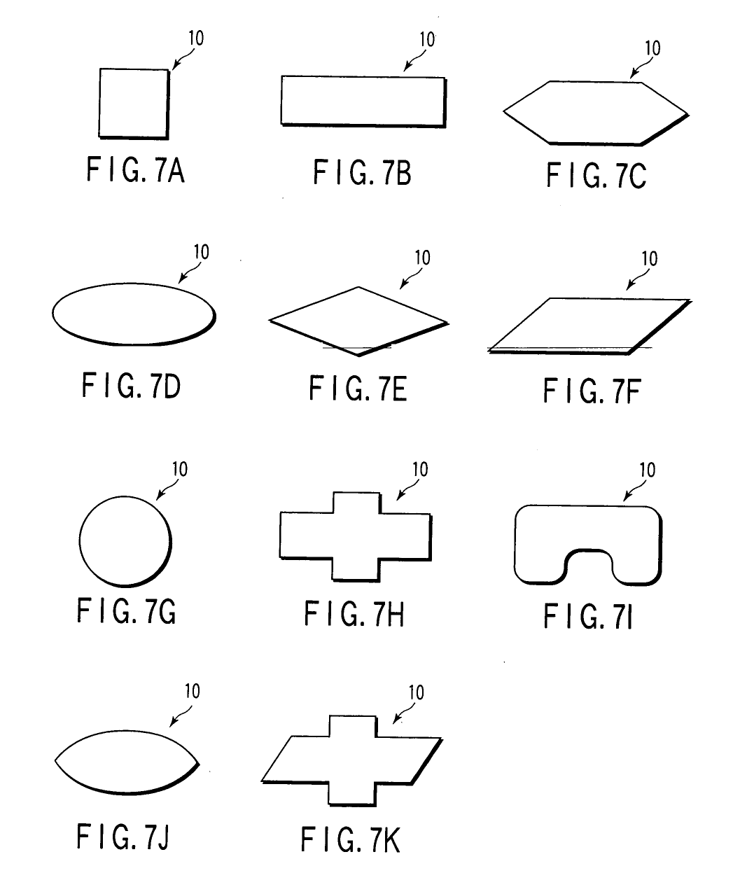

FIGS. 7A to 7K show examples of the planar shape of the MTJ element according to the second embodiment of the present invention. The examples of the planar shape of the MTJ element will be described.

As show in FIGS. 7A to 7K, the planar shape of the MTJ element 10 can be changed variously to, e.g., a square, rectangle, hexagon, ellipse, rhombus, parallelogram, circle, cross, bean shape (concave shape), eye shape, or cross with a parallelogram. The angular portions of each shape may be round, as a matter of course.

### (c) Sectional Shape

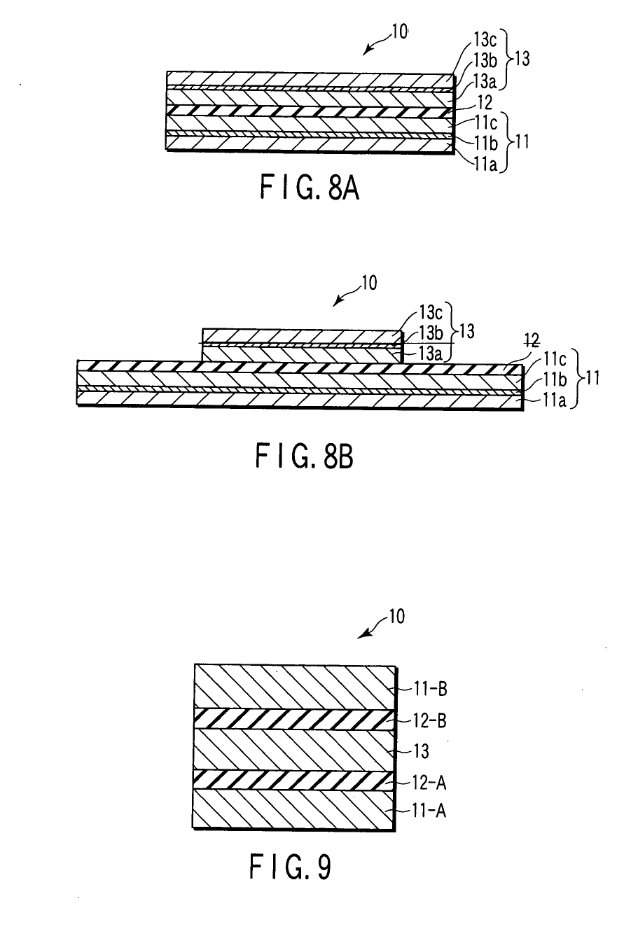

FIGS. 8A and 8B show examples of the sectional shape of the MTJ element according to the second embodiment of the present invention. The examples of the sectional shape of the MTJ element will be described below.

As shown in FIG. 8A, all layers of the MTJ element 10 may be processed at once to make the side surfaces of all layers coincide with each other.

As shown in FIG. 8B, the horizontal surface size of the recording layer 13 may be smaller than that of the fixed layer 11 and tunnel barrier layer 12 so that the MTJ element 10 has a convex sectional shape.

As shown in FIGS. 8A and 8B, the fixed layer 11 may have a three-layered structure including a ferromagnetic layer 11a, nonmagnetic layer 11b, and ferromagnetic layer 11c. The ferromagnetic layers 11a and 11c may be coupled ferromagnetically or antiferromagnetically. The recording layer 13 may have a three-layered structure including a ferromagnetic layer 13a, nonmagnetic layer 13b, and ferromagnetic layer 13c. The ferromagnetic layers 13a and 13c may be coupled ferromagnetically or antiferromagnetically. Only one of the fixed layer 11 and recording layer 13 may have a three-layered structure.

### (d) Double Junction Structure

The MTJ element 10 need not always have the above-described single junction structure and may have a double junction structure.

FIG. 9 is a sectional view of an MTJ element with a double junction structure according to the second embodiment of the present invention. The double junction structure of the MTJ element will be described below.

As shown in FIG. 9, the MTJ element 10 may have a double junction structure including a first fixed layer 11-A, second fixed layer 11-B, recording layer 13, first tunnel barrier layer 12-A, and second tunnel barrier layer 12-B. The recording layer 13 is provided between the first fixed layer 11-A and the second fixed layer 11-B. The first tunnel barrier layer 12-A is provided between the first fixed layer 11-A and the recording layer 13. The second tunnel barrier layer 12-B is provided between the second fixed layer 11-B and the recording layer 13.

In the double junction structure, the bias voltage per tunnel junction is ½ the applied voltage, as compared to the single junction structure. Hence, the decrease in magnetoresistive (MR) ratio caused by an increase in bias voltage can be suppressed.

### (e) Materials

Examples of the materials of the fixed layer 11 and recording layer 13 are as follows. For example, Fe, Co, Ni, a layered film thereof, an alloy thereof, magnetite having a high spin polarizability, an oxide such as CrO₂ or RXMnO_{3-Y} (R: rare earth, X: Ca, Ba, or Sr), or a Heusler alloy such as NiMnSb or PtMnSb is preferably used. The magnetic materials may contain a small amount of nonmagnetic element such as Ag, Cu, Au, Al, Mg, Si, Bi, Ta, B, C, O, N, Pd, Pt, Zr, Ir, W, Mo, or Nb as long as the ferromagnetism is not lost.

For the tunnel barrier layer 12, various dielectric materials such as AlOx (e.g., Al₂O₃), MgOx, SiO₂, AlN, Bi₂O₃, MgF₂, CaF₂, SrTiO₂, and AlLaO₃ can be used. These dielectric materials may contain oxygen, nitrogen, or fluorine defects.

When the fixed layer 11 and recording layer 13 have a three-layered structure of ferromagnetic layer/nonmagnetic layer/ferromagnetic layer, examples of the ferromagnetic layer/nonmagnetic layer/ferromagnetic layer are NiFe/Ru/NiFe, CoFe/Ru/CoFe, CoFe/Cu/NiFe, NiFe/Cu/NiFe, CoFe/Cu/CoFe, and CoFe/Cu/NiFe.

To fix the magnetization of the fixed layer 11, a magnetization fixing layer is provided adjacent to the fixed layer 11. Examples of the material of the magnetization fixing layer are PtMn and IrMn.

### THIRD EMBODIMENT

In the third embodiment, a magnetoresistive random access memory having an MTJ element formed by using a mask by imprint lithography will be described.

### (a) Select Transistor Cell

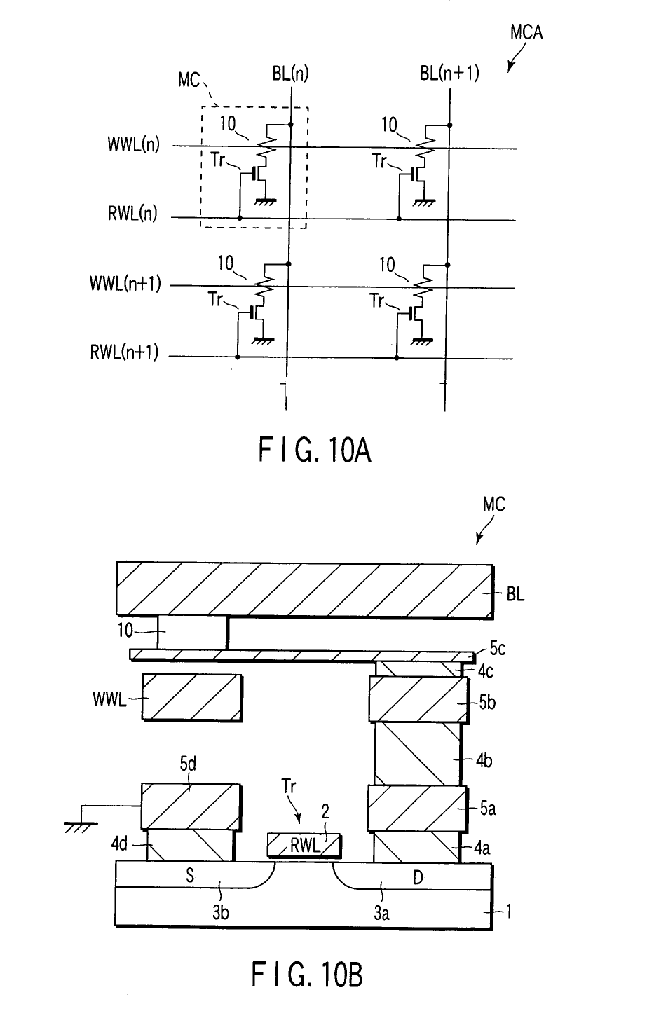

FIGS. 10A and 10B show select transistor memory cells of the magnetoresistive random access memory according to the third embodiment of the present invention. The select transistor cell structure will be described below.

As shown in FIGS. 10A and 10B, one cell MC having a select transistor structure includes one MTJ element 10, a transistor (e.g., a MOS transistor) Tr connected to the MTJ element 10, a write word line WWL, and a bit line BL. A memory cell array MCA is formed by laying out a plurality of memory cells MC in an array.

More specifically, one terminal of the MTJ element 10 is connected to one end (drain diffusion layer) 3a of the current path of the transistor Tr through a base metal layer 5c, contacts 4a, 4b, and 4c, and interconnections 5a and 5b. The other terminal of the MTJ element 10 is connected to the bit line BL. The write word line WWL electrically disconnected from the MTJ element 10 is provided under the MTJ element 10. The other end (source diffusion layer) 3b of the current path of the transistor Tr is connected to, e.g., ground through a contact 4d and interconnection 5d. A gate electrode 2 of the transistor Tr functions as a read word line RWL.

In the above-described select transistor memory cell MC, the data write and read are executed in the following way.

In the write operation, a magnetic field write is executed in the following way. Write currents Iw1 and Iw2 are supplied to the bit line BL and write word line WWL corresponding to a selected one of the plurality of MTJ elements 10, respectively. A synthetic field of magnetic fields generated by the write currents Iw1 and Iw2 is applied to the MTJ element 10. A state wherein the magnetization directions of the fixed layer 11 and recording layer 13 are almost antiparallel is defined as a “1” state. A state wherein the magnetization directions are almost parallel is defined as a “0” state. In this way, a binary data write is implemented.

The read operation is executed in the following way by using the transistor Tr which functions as a read switching element. The bit line BL and read word line RWL corresponding to the selected MTJ element 10 are selected. A read current Ir is supplied in a direction perpendicular to the film surface of the MTJ element 10. When the magnetization of the fixed layer 11 (when the fixed layer 11 has a multilayer structure, the magnetization of the ferromagnetic layer closest to the recording layer 13) and the magnetization of the recording layer 13 (when the recording layer 13 has a multilayer structure, the magnetization of the ferromagnetic layer closest to the fixed layer 11) are almost parallel (e.g., “0” state), the resistance is low. When the magnetizations are almost antiparallel (e.g., “1” state), the resistance is high. The resistance value by the tunneling magnetoresistive (TMR) effect is measured and compared with the resistance value of a separately provided reference cell, thereby discriminating the “1” and “0” states of the MTJ element 10.

### (b) Select Diode Cell

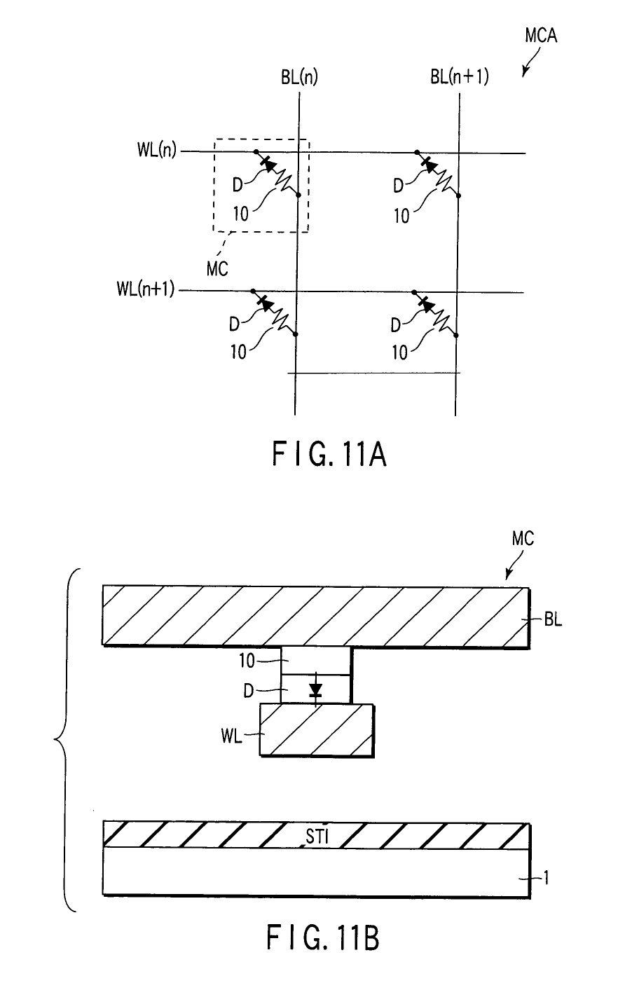

FIGS. 11A and 11B show select diode memory cells of the magnetoresistive random access memory according to the third embodiment of the present invention. The select diode cell structure will be described below.

As shown in FIGS. 11A and 11B, one cell MC having a select diode structure includes one MTJ element 10, a diode D connected to the MTJ element 10, the bit line BL, and the word line WL. The memory cell array MCA is formed by laying out a plurality of memory cells MC in an array.

The diode D is, e.g., a p-n junction diode including a p-type semiconductor layer and an n-type semiconductor layer. One terminal (e.g., the p-type semiconductor layer) of the diode D is connected to the MTJ element 10. The other terminal (e.g., the n-type semiconductor layer) of the diode D is connected to the word line WL. In the structure shown in FIGS. 11A and 11B, a cur-rent flows from the bit line BL to the word line WL.

The location or direction of the diode D can be changed variously. For example, the diode D may be arranged in a direction to supply a current from the word line WL to the bit line BL. The diode D may be formed in a semiconductor substrate 1. The diode D may be a Schottky junction diode including a semiconductor layer and a metal layer.

The data write operation of the select diode memory cell is the same as that of the above-described select transistor cell, and a magnetic field write is executed

The data read operation is also almost the same as that of the select transistor cell. In the select diode cell, the diode D is used as a read switching element. More specifically, the biases of the bit line BL and word line WL are controlled by using the rectifying effect of the diode D such that an unselected MTJ element 10 is reverse-biased. Accordingly, the read current Ir is supplied to only the selected MTJ element 10.

### (c) Cross-Point Cell

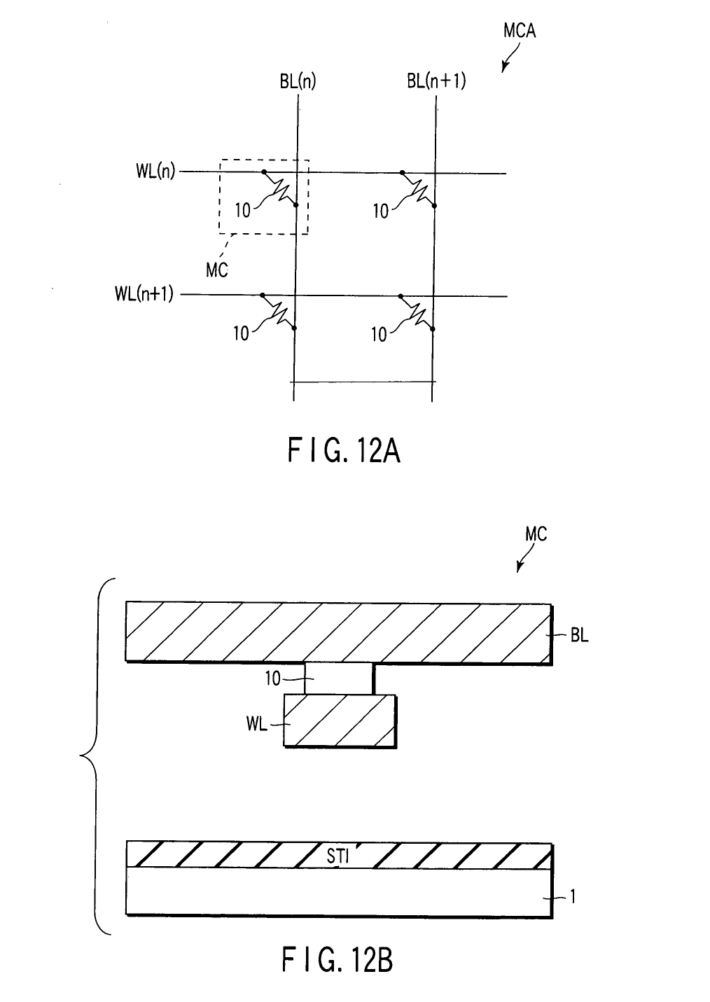

FIGS. 12A and 12B show cross-point memory cells of the magnetoresistive random access memory according to the third embodiment of the present invention. The cross-point cell structure will be described below.

As shown in FIGS. 12A and 12B, one cell MC having a cross-point structure includes one MTJ element 10, the bit line BL, and the word line WL. The memory cell array MCA is formed by laying out a plurality of memory cells MC in an array.

More specifically, the MTJ element 10 is arranged near the intersection between the bit line BL and the word line WL. One terminal of the MTJ element 10 is connected to the word line WL. The other terminal of the MTJ element 10 is connected to the bit line BL.

The data write operation of the cross-point memory cell is the same as that of the above-described select transistor cell, and a magnetic field write is executed. In the data read operation, the read current Ir is supplied to the bit line BL and word line WL connected to the selected MTJ element 10, thereby reading out the data of the MTJ element 10.

### (d) Toggle Cell

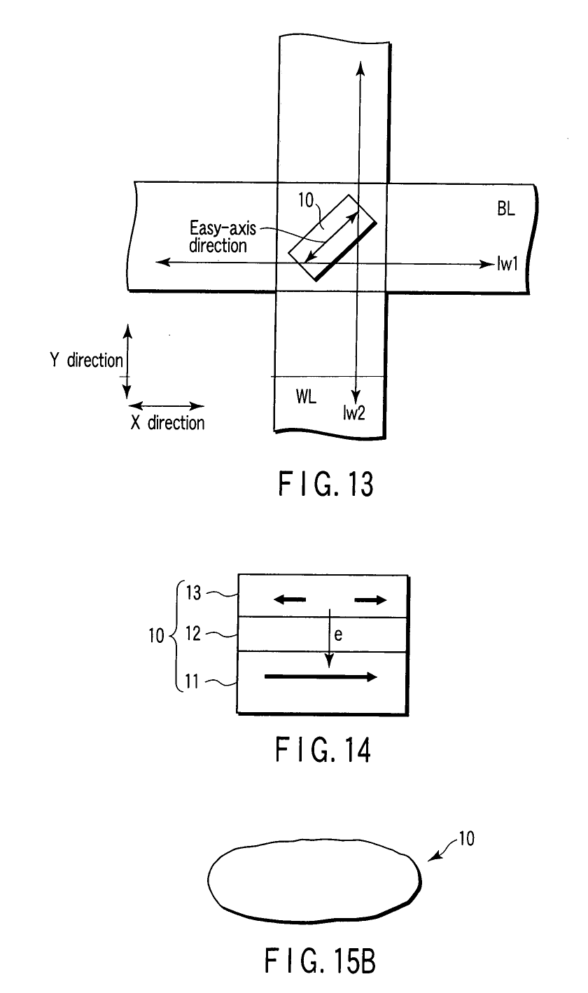

FIG. 13 is a plan view showing a toggle memory cell of the magnetoresistive random access memory according to the third embodiment of the present invention. The toggle cell structure will be described below.

As shown in FIG. 13, in the toggle cell, the MTJ element 10 is arranged such that the axis of easy magnetization of the MTJ element 10 is tilted with respect to the running direction (X direction) of the bit line BL or the running direction (Y direction) of the word line WL. In other words, the MTJ element 10 is tilted with respect to the direction of the write current Iw1 to be supplied to the bit line BL or the direction of the write current Iw2 supplied to the word line WL. The tilt of the MTJ element 10 is, e.g., about 30° to 60°, and preferably, about 45°. At least the recording layer 13 of the MTJ element 10 preferably has an antiferromagnetic coupling structure.

In the above-described toggle memory cell, the data write and read are executed in the following way.

The write operation is executed in the following way. In the toggle write, before arbitrary data is written in the selected cell, the data of the selected cell is read out. If it is determined by reading out the data of the selected cell that the arbitrary data has already been written, no write is executed. If data different from the arbitrary data is written, the write is executed to rewrite the data.

After the above-described check cycle, if data must be written in the selected cell, the two write interconnections (bit line BL and word line WL) are sequentially turned on. The write interconnection turned on first is turned off. Then, the write interconnection turned on later is turned off. For example, the procedures comprise four cycles: the word line WL is turned on to supply the write current Iw2 → the bit line BL is turned on to supply the write current Iw1 → the word line WL is turned off to stop supplying the write current Iw2 → the bit line BL is turned off to stop supplying the write current Iw1.

In the data read operation, the read current Ir is supplied to the bit line BL and word line WL connected to the selected MTJ element 10, thereby reading out the data of the MTJ element 10.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A magnetoresistive element manufacturing method comprising:
forming a material layer on a substrate, the material layer including a fixed layer, a recording layer, and a first nonmagnetic layer sandwiched between the fixed layer and the recording layer;
forming a mask material on the material layer;
forming a first mask with a desired pattern by processing the mask material by using imprint lithography; and
forming a magnetoresistive element with the desired pattern by processing the recording layer, the fixed layer, and the first nonmagnetic layer at once by using the first mask, the magnetoresistive element being a memory element in an magnetic random access memory.

2-4. (canceled)

5. The method according to claim 1, wherein a radius of curvature of a corner of the magnetoresistive element is not more than 21 nm.

6. The method according to claim 1, wherein a planar shape of the magnetoresistive element is a cross shape.

7. The method according to claim 1, further comprising:
forming a mold with the desired pattern;
forming the first mask with the desired pattern by pressing the mold against the mask material; and
separating the mold from the first mask.

8. The method according to claim 1, wherein the mask material is a thermosetting material.

9. The method according to claim 1, wherein the mask material is a photo-setting material.

10. The method according to claim 1, wherein at lest one of the fixed layer and the recording layer comprises:
a first ferromagnetic layer;
a second ferromagnetic layer which is antiferromagnetically or ferromagnetically coupled to the first ferromagnetic layer; and
a second nonmagnetic layer sandwiched between the first ferromagnetic layer and the second ferromagnetic layer.

11. A magnetic memory device manufacturing method comprising:
forming a material layer on a substrate, the material layer including a fixed layer, a recording layer, and a nonmagnetic layer sandwiched between the fixed layer and the recording layer;
forming a mask material on the material layer;
forming a first mask with a desired pattern by processing the mask material by using imprint lithography;
forming a magnetoresistive element with the desired pattern by processing the recording layer, the fixed layer, and the nonmagnetic layer at once by using the first mask, the magnetoresistive element being a memory element in an magnetic random access memory; and
forming a bit line and a word line above and under the magnetoresistive element.

12. The method according to claim 11, further comprising:
forming one of a transistor and a diode to be connected to the magnetoresistive element.

13. The method according to claim 11, wherein a direction of an axis of easy magnetization of the magnetoresistive element is tilted 30° to 60° with respect to a running direction of one of the bit line and the word line.

14-16. (canceled)

17. The method according to claim 11, wherein a radius of curvature of a corner of the magnetoresistive element is not more than 21 nm.

18. The method according to claim 11, wherein a planar shape of the magnetoresistive element is a cross shape.

19. The method according to claim 11, wherein the mask material is a thermosetting material.

20. The method according to claim 11, wherein the mask material is a photo-setting material.
